(19) United States
(12) Patent Application Publication
(10) Pub. No.: US 2024/0421216 A1
(43) Pub. Date: Dec. 19, 2024

(54) INTEGRATED CIRCUIT SEMICONDUCTOR DEVICE

(71) Applicant: SAMSUNG ELECTRONICS CO., LTD., SUWON-SI (KR)

(72) Inventors: Sunggyu Han, Suwon-si (KR); Heonjong Shin, Suwon-si (KR); Juneyoung Park, Suwon-si (KR); Sanghee Lee, Suwon-si (KR); Jaeran Jang, Suwon-si (KR); Mingi Chung, Suwon-si (KR)

(21) Appl. No.: 18/676,858

(22) Filed: May 29, 2024

(30) Foreign Application Priority Data
Jun. 14, 2023 (KR) 10-2023-0076418

(51) Int. Cl. H01L 29/775; H01L 27/088; H01L 29/06; H01L 29/08; H01L 29/66

(52) U.S. Cl. CPC H01L 29/775; H01L 27/0886; H01L 29/0603; H01L 29/0673; H01L 29/0847; H01L 29/66439

(57) ABSTRACT

An integrated circuit semiconductor device includes a base layer including a first surface and a second surface, a gate structure on the first surface of the base layer, a first source and drain region on a side of the gate structure, a second source and drain region on another side of the gate structure, a first placeholder in the base layer in a lower portion of the first source and drain region and electrically connected to the first source and drain region, a second placeholder in the base layer in a lower portion of the second source and drain region, and a metal power rail on the first placeholder and the second placeholder on the second surface of the base layer and electrically connected to the first placeholder.

### CROSS-REFERENCE TO RELATED APPLICATION

This application is based on and claims priority under 35 U.S.C. § 119 to Korean Patent Application No. 10-2023-0076418, filed on Jun. 14, 2023, in the Korean Intellectual Property Office, the disclosure of which is incorporated by reference herein in its entirety.

### TECHNICAL FIELD

The inventive concept relates to an integrated circuit semiconductor device, and more particularly, to an integrated circuit semiconductor device capable of reducing a wiring resistance and preventing the occurrence of a short circuit or a leakage current between metal layers.

### DESCRIPTION OF RELATED ART

An integrated circuit semiconductor device needs to be reliably formed on a substrate. As integrated circuit devices have become highly integrated, a wiring resistance has increased and the possibility of a short circuit or a leakage current has increased.

### SUMMARY

The inventive concept provides an integrated circuit semiconductor device capable of reducing a wiring resistance and preventing the occurrence of a short circuit or a leakage current.

According to an aspect of the inventive concept, there is provided an integrated circuit semiconductor device including a base layer including a first surface and a second surface opposite to the first surface, a gate structure on the first surface of the base layer, a first source and drain region on a first side of the gate structure, a second source and drain region on a second side of the gate structure, a first placeholder disposed in the base layer in a lower portion of the first source and drain region and electrically connected to the first source and drain region, a second placeholder disposed in the base layer in a lower portion of the second source and drain region, a metal power rail disposed on the first placeholder and the second placeholder on the second surface of the base layer and electrically connected to the first placeholder, and a source and drain metal wiring layer electrically connected to the second source and drain region on the first surface of the base layer.

According to another aspect of the inventive concept, there is provided an integrated circuit semiconductor device including a base layer including a first surface and a second surface opposite to the first surface, a nanosheet stacking structure disposed on the first surface of the base layer and including a plurality of nanosheets spaced apart from each other in a vertical direction, a gate structure disposed between the plurality of nanosheets and on an uppermost nanosheet of the plurality of nanosheets, a first source and drain region on a first side of the gate structure, a second source and drain region on a second side of the gate structure, a first placeholder contacting the first source and drain region in the base layer in a lower portion of the first source and drain region, and including a metal layer, a second placeholder contacting the second source and drain region in the base layer in a lower portion of the second source and drain region, and including an insulating layer, a metal power rail disposed on the second surface of the base layer and electrically connected to the first placeholder, and a source and drain metal wiring layer disposed on the nanosheet stacking structure and the gate structure and electrically connected to the second source and drain region.

According to another aspect of the inventive concept, there is provided an integrated circuit semiconductor device including a substrate including a first surface and a second surface opposite to the first surface, a nanosheet stacking structure disposed on the first surface of the substrate and including a plurality of nanosheets spaced apart from each other in a vertical direction, a gate structure disposed between the plurality of nanosheets and on an uppermost nanosheet of the plurality of nanosheets, and including a plurality of gate insulating layers and a plurality of gate electrodes, a first source and drain region on a first side of the gate structure on the first surface of the substrate, a second source and drain region on a second side of the gate structure on the first surface of the substrate, wherein the first side is opposite to the second side, a first placeholder contacting the first source and drain region in the substrate in a lower portion of the first source and drain region, and includes a metal layer, a second placeholder contacting the second source and drain region in the substrate in a lower portion of the second source and drain region, and includes an insulating layer, a metal power rail disposed on the first placeholder and the second placeholder on the second surface of the substrate, electrically connected to the first placeholder through a rail via, and electrically insulated from the second placeholder, a source and drain metal wiring layer disposed on the nanosheet stacking structure and the gate structure and electrically connected to the second source and drain region through a via plug, and a gate metal wiring layer disposed on the gate structure and electrically connected to the plurality of gate electrodes through a contact plug.

### BRIEF DESCRIPTION OF THE DRAWINGS

Embodiments will be more clearly understood from the following detailed description taken in conjunction with the accompanying drawings in which:

FIG. 1 is a layout diagram of an integrated circuit semiconductor device according to an embodiment;

FIG. 2 is a cross-sectional view of the integrated circuit semiconductor device taken along a line II-II′ of FIG. 1;

FIG. 3 is a cross-sectional view of the integrated circuit semiconductor device taken along a line III-III′ of FIG. 1;

FIG. 4 is a cross-sectional views illustrating a method of manufacturing an integrated circuit semiconductor device according to an embodiment;

FIG. 5 is a cross-sectional views illustrating a method of manufacturing an integrated circuit semiconductor device according to an embodiment;

FIG. 6A and FIG. 6B are cross-sectional views illustrating a method of manufacturing an integrated circuit semiconductor device according to an embodiment;

FIG. 7 is a cross-sectional views illustrating a method of manufacturing an integrated circuit semiconductor device according to an embodiment;

FIG. 8 is a cross-sectional views illustrating a method of manufacturing an integrated circuit semiconductor device according to an embodiment;

FIG. 9 is a cross-sectional views illustrating a method of manufacturing an integrated circuit semiconductor device according to an embodiment;

FIG. 10 is a cross-sectional views illustrating a method of manufacturing an integrated circuit semiconductor device according to an embodiment;

FIG. 11 is a cross-sectional views illustrating a method of manufacturing an integrated circuit semiconductor device according to an embodiment;

FIG. 12 is a cross-sectional views illustrating a method of manufacturing an integrated circuit semiconductor device according to an embodiment;

FIG. 13 is a cross-sectional views illustrating a method of manufacturing an integrated circuit semiconductor device according to an embodiment;

FIG. 14 is a cross-sectional views illustrating a method of manufacturing an integrated circuit semiconductor device according to an embodiment;

FIG. 15 is a block diagram illustrating a configuration of a semiconductor chip including an integrated circuit semiconductor device according to an embodiment;

FIG. 16 is a block diagram illustrating a configuration of a semiconductor chip including an integrated circuit semiconductor device according to an embodiment;

FIG. 17 is a block diagram illustrating a configuration of an electronic device including an integrated circuit semiconductor device according to an embodiment; and

FIG. 18 is an equivalent circuit diagram of a static random access memory (SRAM) cell according to an embodiment.

### DETAILED DESCRIPTION

Hereinafter, embodiments of the inventive concept will be described in detail with reference to the accompanying drawings. The inventive concept may be implemented in one or more embodiments, or a combination of embodiments. Therefore, the inventive concept should not be construed as being limited to an embodiment.

In the specification, singular forms of elements may include plural forms unless the context clearly indicates otherwise. In the specification, the drawings may be exaggerated in order to clearly describe the inventive concept.

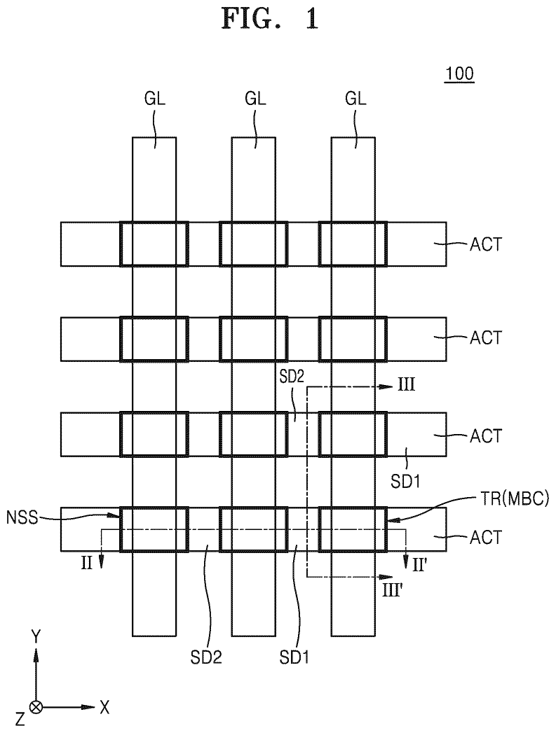

FIG. 1 is a layout diagram of an integrated circuit semiconductor device according to an embodiment.

Specifically, in FIG. 1, an X direction may be a first horizontal direction, and a Y direction may be a second horizontal direction perpendicular to the first horizontal direction. A Z direction may be a vertical direction perpendicular to a plane formed by the X direction and the Y direction. Hereinafter, a layout of an integrated circuit semiconductor device 100 is described in detail, but the inventive concept is not limited to the layout of FIG. 1.

The integrated circuit semiconductor device 100 may include a plurality of active fins ACT extending in a first horizontal direction (X direction) and spaced apart in a second horizontal direction (Y direction). An active pin of the active fin ACT may be a P-type active pin or an N-type active pin. The integrated circuit semiconductor device 100 may include a plurality of gate structures GL extending in the second horizontal direction (Y direction) perpendicular to the first horizontal direction (X direction) and spaced apart in the first horizontal direction (X direction). The gate structures GL may include a gate insulating layer and a gate electrode.

In the integrated circuit semiconductor device 100, nanosheet stacking structures NSS may be respectively positioned at overlapping portions where the active fins ACT and the gate structures GL intersect. A first source and drain region SD1 or a second source and drain region SD2 may be formed on a side of the nanosheet stacking structures NSS. Each of the nanosheet stacking structures NSS may be formed in the overlapping portion where the active fin ACT and a gate structure GL intersect. The first source and drain region SD1 may be a first source region or a first drain region. The second source and drain region SD2 may be a second source region or a second drain region.

In the integrated circuit semiconductor device 100, transistors TR including the nanosheet stacking structures NSS may be disposed at the overlapping portions where the active fins ACT and the gate structures GL intersect each other, and the gate electrodes GL are formed. The transistors TR may be a three-dimensional (3D) transistors. The transistors TR may include multi-bridge channel transistors MBCs including the nanosheet stacking structures NSS and the gate structures GL.

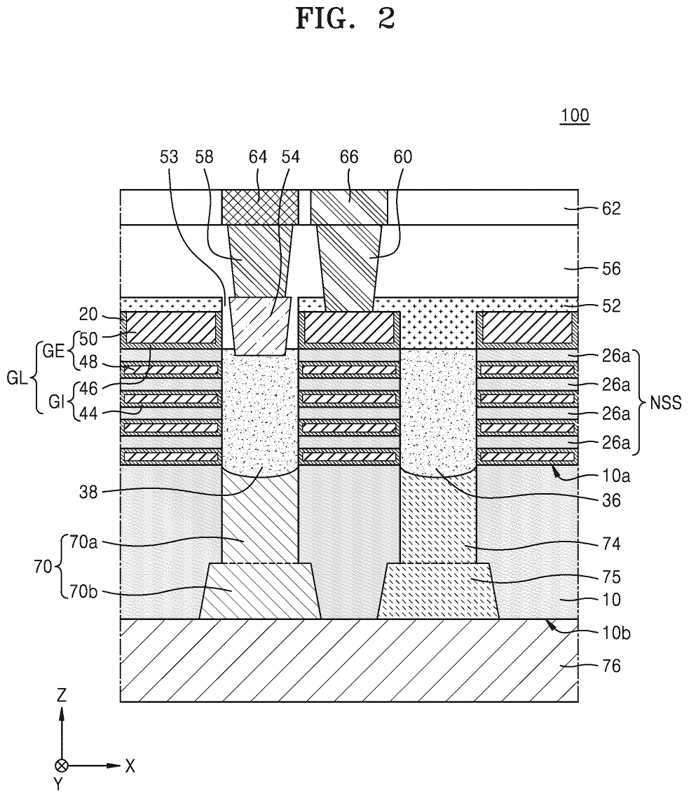

FIG. 2 is a cross-sectional view of the integrated circuit semiconductor device 100 taken along a line II-II′ of FIG. 1.

Specifically, the integrated circuit semiconductor device 100 may include a base layer 10, the nanosheet stacking structure NSS, and the gate structure GL. The base layer 10 may include a first surface 10a and a second surface 10b. The first surface 10a and the second surface 10b may be disposed opposite each other. The second surface may face the first surface 10a in a reverse vertical direction (−Z direction). In some embodiments, the base layer 10 may be a substrate, such as a bulk silicon substrate. In some embodiments, the base layer 10 may be an insulating layer or an insulating substrate.

The nanosheet stacking structure NSS and the gate structure GL may be formed on the first surface 10a of the base layer 10. The nanosheet stacking structure NSS may include a plurality of nanosheets 26a spaced apart from each other in a vertical direction (Z direction). The nanosheets 26a may each include a silicon layer.

The gate structure GL may be disposed between the plurality of nanosheets 26a and on the uppermost nanosheet 26a. The gate structure GL may be disposed between the plurality of nanosheets 26a in the vertical direction (Z direction) and on the uppermost nanosheet 26a The gate structure GL may include a plurality of gate insulating layers GI and a plurality of gate electrodes GE. In some embodiments, the gate insulating layers GI may each include a silicon oxide layer. The gate electrode GE may include a metal layer. In some embodiments, a spacer 20 may be formed on a sidewall of the gate electrode GE.

The gate insulating layers GI may include a sub gate insulating layer 44 formed between the nanosheets 26a and a main gate insulating layer 46 formed on the uppermost nanosheet 26a. In some embodiments, the gate insulating layers GI may each include a high-k layer. In some embodiments, the sub gate insulating layer 44 and the main gate insulating layer 46 may include a same material.

In some embodiments, the main gate insulating layer 46 and the spacer 20 may include the same material. Accordingly, in FIG. 2, for convenience, a boundary line between the main gate insulating layer 46 and the spacer 20 is not indicated.

The gate electrode GE may include a sub gate electrode 48 formed between the nanosheets 26a and a main gate electrode 50 formed on the uppermost nanosheet 26a. The sub gate electrode 48 and the main gate electrode 50 may include a same material.

The integrated circuit semiconductor device 100 may include a first source and drain region 36 and a second source and drain region 38. The first source and drain region 36 may be formed on a first side of the gate structure GL and on the first surface 10a of the base layer 10. In some embodiments, the first source and drain region 36 may be a source region or a drain region. For example, the first source and drain regions 36 may be source regions.

The second source and drain region 38 may be formed on a second side of the gate structure GL, opposite the first source and drain regions 36, and on the first surface 10a of the base layer 10. In some embodiments, the second source and drain region 38 may be a source region or a drain region. For example, the second source and drain region 38 may be a drain region.

In some embodiments, the first source and drain region 36 and the second source and drain region 38 may be regions in which an epitaxially grown Silicon (Si) layer, an epitaxially grown Silicon Carbide (SiC) layer, or an epitaxially grown Silicon Germanium (SiGe) layer is doped with impurities. In some embodiments, impurities may be boron (B), arsenic (As), or phosphorus (P).

The integrated circuit semiconductor device 100 may include a first placeholder 74 and a second placeholder 70. The first placeholder 74 may be disposed in the base layer 10 of a lower portion of the first source and drain region 36. The first placeholder 74 may be self-aligned and formed below the first source and drain region 36. The first placeholder 74 may include a metal layer. Accordingly, the first placeholder 74 may be electrically connected to the first source and drain region 36.

The second placeholder 70 may be disposed in the base layer 10 of a lower portion of the second source and drain region 38. The second placeholder 70 may be self-aligned and formed below the second source and drain region 38. The second placeholder 70 may include an insulating layer. Accordingly, the second placeholder 70 may not be electrically connected to the second source and drain region 38. The first placeholder 74 and the second placeholder 70 may be spaced apart from each other in a first horizontal direction (X direction).

The second placeholder 70 may include a holder insulating layer 70a contacting the second source and drain region 38 and an insulating via 70b contacting the holder insulating layer 70a. For example, the holder insulating layer 70a may be disposed on the insulating via 70b. In some embodiments, when a thickness of the base layer 10 is small, the insulating via 70b may be omitted. In this case, the second placeholder 70 may include only the holder insulating layer 70a.

The integrated circuit semiconductor device 100 may include a rail via 75 and a metal power rail 76. The rail via 75 may contact the first placeholder 74. The rail via 75 may contact the first placeholder 74 in the base layer 10. In some embodiments, the first placeholder 74 and the rail via 75 may be formed as a single body. For example, the first placeholder 74 and the rail via 75 may be simultaneously formed of a same material.

The metal power rail 76 may be disposed on the rail via 75 and the insulating via 70b and on the second surface 10b of the base layer 10. The metal power rail 76 may be electrically connected to the first placeholder 74 through the rail via 75. A width of the rail via 75 may be greater than a width of the first placeholder 74 in a first horizontal direction (X direction). The metal power rail 76 may be directly connected to the first placeholder 74 through the rail via 75. The metal power rail 76 may be disposed on the second surface 10b of the base layer 10 and may extend in the first horizontal direction (X direction). The metal power rail 76 may transfer an operating voltage to the first source and drain region 36 through the rail via 75.

In some embodiments, when the thickness of the base layer 10 is small, the insulation via 70b and the rail via 75 may be omitted. In this case, the metal power rail 76 may be formed on the first placeholder 74 on the second surface 10b of the base layer 10 and on the holder insulating layer 70a of the second placeholder 70.

The integrated circuit semiconductor device 100 may include a first interlayer insulating layer 52, a sidewall insulating layer 53, a second interlayer insulating layer 56, a first contact plug 54, a first via plug 58, and a second contact plug 60. The first interlayer insulating layer 52 and the second interlayer insulating layer 56 may be sequentially formed. The second interlayer insulating layer 56 may be formed on the first interlayer insulating layer 52. The first interlayer insulating layer 52 and the second interlayer insulating layer 56 may be formed on the nanosheet stacking structure NSS and the gate structure GL.

In some embodiments, the first interlayer insulating layer 52 may include a silicon nitride layer, and the sidewall insulating layer 53 and the second interlayer insulating layer 56 may each include a silicon oxide layer. In some embodiments, the first interlayer insulating layer 52, the sidewall insulating layer 53, and the second interlayer insulating layer 56 may include the same material, such as a silicon oxide layer or a silicon nitride layer.

A first contact plug 54 and a first via plug 58 electrically connected to the second source and drain region 38 may be formed in the first interlayer insulating layer 52, the sidewall insulating layer 53, and the second interlayer insulating layer 56. The first via plug 58 may be formed on the first contact plug 54. In some embodiments, the first via plug 58 may include a metal layer.

A second contact plug 60 electrically connected to the uppermost gate electrode 50 of the gate structure GL may be formed in the first interlayer insulating layer 52 and the second interlayer insulating layer 56. The second contact plug 60 may include a metal layer.

The first contact plug 54 and the first via plug 58 may be formed on the second source and drain region 38, and the second contact plug 60 may be formed on the uppermost gate electrode 50 of the gate structure GL. The first contact plug 54 and the first via plug 58 may be spaced apart from the second contact plug 60 in the first horizontal direction (X direction). The first contact plug 54 and the first via plug 58 may be spaced apart from the second contact plug 60, with the second interlayer insulating layer 56 disposed therebetween.

The integrated circuit semiconductor device 100 may include a third interlayer insulating layer 62, a source and drain metal wiring layer 64, and a gate metal wiring layer 66. The third interlayer insulating layer 62 may be disposed on the second interlayer insulating layer 56. In some embodiments, the third interlayer insulating layer 62 may include a silicon oxide layer. The source and drain metal wiring layer 64 may be formed in the third interlayer insulating layer 62. The source and drain metal wiring layer 64 may be formed on the first via plug 58. Accordingly, the source and drain metal wiring layer 64 may be electrically connected to the second source and drain region 38 through the first via plug 58 and the first contact plug 54.

The gate metal wiring layer 66 may be formed in the third interlayer insulating layer 62. The gate metal wiring layer 66 may be formed on the second contact plug 60. Accordingly, the gate metal wiring layer 66 may be electrically connected to the gate structure GL through the second contact plug 60. The gate metal wiring layer 66 may be electrically connected to the uppermost gate electrode 50 of the gate structure GL through the second contact plug 60. The source and drain metal wiring layer 64 and the gate metal wiring layer 66 may be disposed on an upper portion of the first surface 10a of the base layer 10 and extend in a second horizontal direction (Y direction). The source and drain metal wiring layer 64 may be spaced apart from the gate metal wiring layer 66 in the first horizontal direction (X direction). The source and drain metal wiring layer 64 may be spaced apart from the gate metal wiring layer 66, with the third interlayer insulating layer 62 disposed therebetween.

In the integrated circuit semiconductor device 100 as described herein a wiring length or a wiring area may be reduced, and when the metal power rail 76 directly applies the operating voltage to the first source and drain region 36 through the rail via 75 and the first placeholder 74, a wiring resistance may be reduced. The integrated circuit semiconductor device 100 may reduce or prevent the occurrence of a short circuit between the second placeholder 70 including an insulating layer and the first placeholder 74 including a metal layer. The integrated circuit semiconductor device 100 having the second placeholder 70 including the insulating layer may reduce or prevent the occurrence of a leakage current between the second source and drain region 38 and the metal power rail 76.

In addition, when the integrated circuit semiconductor device 100 having a reduced wiring length or wiring area transmits a voltage to the second source and drain region 38 through the first via plug 58 and the first contact plug 54 in the upper portion of the first surface 10a of the base layer 10, the wiring resistance may be reduced. When the integrated circuit semiconductor device 100 having a reduced wiring length or wiring area applies a voltage to the gate structure GL from the upper portion of the first surface 10a of the base layer 10 through the second contact plug 60, the wiring resistance may be reduced.

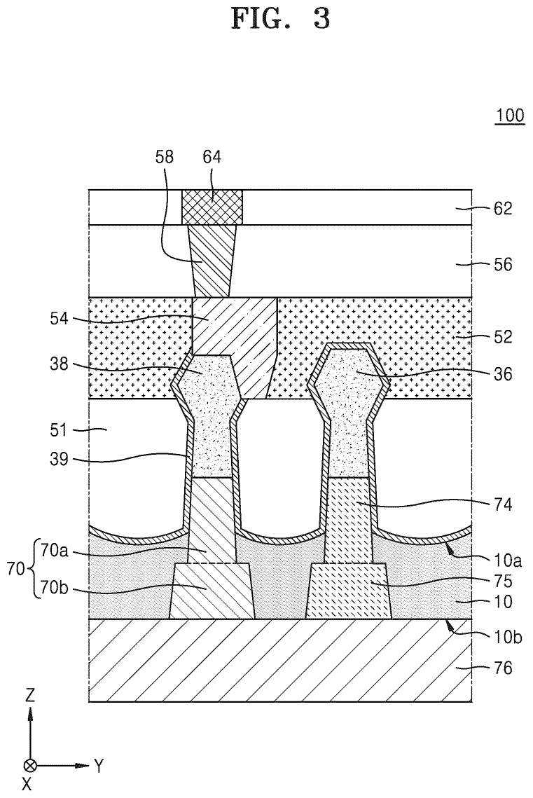

FIG. 3 is a cross-sectional view of the integrated circuit semiconductor device 100 taken along a line III-III′ of FIG. 1.

The descriptions provided with reference to FIG. 2 may be briefly mentioned below or omitted with reference to FIG. 3. The integrated circuit semiconductor device 100 may include the base layer 10, the first source and drain region 36, the second source and drain region 38, and a source and drain separation insulating layer 51. The base layer 10 may include the first surface 10a and the second surface 10b.

The first source and drain region 36 may be disposed above the first surface 10a of the base layer 10. The first source and drain region 36 may be disposed on an upper portion of the first surface 10a of the base layer 10. An upper portion of the first source and drain region 36 may have a pentagonal shape in a cross section. In some embodiments, the first source and drain region 36 may be a source region or a drain region. For example, the first source and drain region 36 may be a source region.

The second source and drain region 38 may be disposed above the first surface 10a of the base layer 10. The second source and drain region 38 may be formed on an upper portion of the first surface 10a of the base layer 10. The second source and drain region 38 may be spaced apart from the first source and drain regions 36 in a second reverse horizontal direction (−Y direction). An upper portion of the second source and drain region 38 may have a pentagonal shape in a cross section. In some embodiments, the second source and drain region 38 may be a source region or a drain region. For example, the second source and drain region 38 may be a drain region.

The source and drain separation insulating layer 51 may separate the first source and drain region 36 and the second source and drain region 38 in a second horizontal direction (Y direction). The source and drain separation insulating layer 51 may include a silicon oxide layer.

The integrated circuit semiconductor device 100 may include the first placeholder 74, the second placeholder 70, and an insulating liner layer 39. A portion of the first placeholder 74 may be disposed in the base layer 10. The first placeholder 74 may be disposed in the base layer 10 of a lower portion of the first source and drain region 36. The first placeholder 74 may include a portion protruding from the first surface 10a of the base layer 10. The first placeholder 74 may include a metal layer and may be electrically connected to the first source and drain region 36.

The second placeholder 70 may be disposed in the base layer 10 of a lower portion of the second source and drain region 38. The second placeholder 70 may include a portion protruding from the first surface 10a of the base layer 10. The second placeholder 70 may include an insulating layer and may not be electrically connected to the second source and drain region 38. The second placeholder 70 may include the holder insulating layer 70a contacting the second source and drain region 38 and the insulating via 70b contacting the holder insulating layer 70a. A portion of the holder insulating layer 70a may be disposed in the base layer 10. The holder insulating layer 70a may include a portion protruding from the first surface 10a of the base layer 10.

The insulating liner layer 39 may be formed on sidewalls of the first source and drain region 36, the second source and drain region 38, the first placeholder 74, and the second placeholder 70. The insulating liner layer 39 may be formed on upper sidewalls of the first placeholder 74 and upper sidewalls of the second placeholder 70. The insulating liner layer 39 may be formed on the first surface 10a of the base layer 10. In some embodiments, the insulating liner layer 39 may include a silicon nitride layer. The insulating liner layer 39 may insulate between the first source and drain region 36 and the second source and drain region 38 and between the first placeholder 74 and the second placeholder 70 in a second horizontal direction (Y direction).

The integrated circuit semiconductor device 100 may include the rail via 75 and the metal power rail 76. The rail via 75 may directly contact the first placeholder 74 in the base layer 10. A width of the rail via 75 may be greater than a width of the first placeholder 74 in a second horizontal direction (Y direction). The metal power rail 76 may be directly connected to the first placeholder 74 through the rail via 75.

The integrated circuit semiconductor device 100 may include the first interlayer insulating layer 52, the second interlayer insulating layer 56, the first contact plug 54, and the first via plug 58. The first contact plug 54 and the first via plug 58 electrically connected to the second source and drain region 38 may be formed in the first interlayer insulating layer 52 and the second interlayer insulating layer 56. The first contact plug 54 and the first via plug 58 electrically connected to the second source and drain region 38 may be formed in the first interlayer insulating layer 52 and the second interlayer insulating layer 56, respectively. The first via plug 58 may be formed on the first contact plug 54. For convenience, FIG. 3 illustrates that the first contact plug 54 may be formed in the first interlayer insulating layer 52.

The integrated circuit semiconductor device 100 may include the third interlayer insulating layer 62 and the source and drain metal wiring layer 64. The source and drain metal wiring layer 64 may be formed on the first via plug 58 in the third interlayer insulating layer 62. Accordingly, the source and drain metal wiring layer 64 may be electrically connected to the second source and drain region 38 through the first via plug 58 and the first contact plug 54. As described herein, the wiring length or wiring area of the integrated circuit semiconductor device 100 may be small, and the wiring resistance may be reduced.

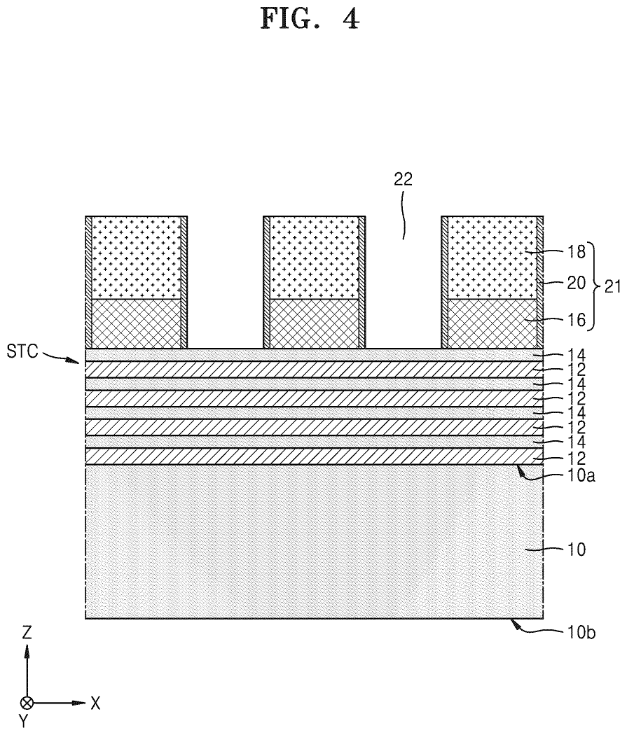

FIGS. 4 to 14 are cross-sectional views illustrating a method of manufacturing an integrated circuit semiconductor device according to an embodiment.

Specifically, FIGS. 4 to 14 are cross-sectional views illustrating a method of manufacturing the integrated circuit semiconductor device 100 of FIG. 2. In FIGS. 4 to 14, the same reference numerals as in FIG. 2 denote the same members. Regarding FIGS. 4 to 14, the descriptions provided with reference to FIG. 2 may be briefly mentioned below or may be omitted.

Referring to FIG. 4, the base layer 10 may be prepared. The base layer 10 may include the first surface 10a and the second surface 10b. The first surface 10a and the second surface 10b may be disposed opposite each other. The first surface 10a may be a front surface, and the second surface 10b may be a rear surface. In some embodiments, the base layer 10 may be a substrate, an insulating layer, or an insulating substrate.

The substrate may include a semiconductor such as Si or Germanium (Ge), or a compound semiconductor such as SiGe, SiC, Gallium Arsenide (GaAs), Indium Arsenide (InAs), or Indium Phosphide (InP). In some embodiments, the substrate may include at least one of a group III-V material or a group IV material.

The group III-V material may be a binary, ternary, or quaternary compound including at least one group III element and at least one group V element. The group III-V material may be a compound including at least one element of Indium (In), Gallium (Ga), and Aluminum (Al) as a group III element and at least one element of As, P, and Sb as a group V element.

For example, the group III-V material may be selected from InP, InzGa1-zAs (0≤z≤1), and AlzGa1-zAs (0≤z≤1). The binary compound may be, for example, any one of InP, GaAs, InAs, Indium Antimonide (InSb), and Gallium Antimonide (GaSb). The ternary compound may be any one of Indium Gallium Phosphide (InGaP), Indium Gallium Arsenide (InGaAs), Aluminum Indium Arsenide (AlInAs), Indium Gallium Antimonide (InGaSb), Gallium Arsenic Antimonide (GaAsSb), and Gallium Arsenic Phosphide (GaAsP). The group IV material may be Si or Ge. However, the group III-V material and the group IV material usable in the integrated circuit semiconductor device according to the inventive concept are not limited to those described herein.

The group III-V material and the group IV material such as Ge may be used as channel materials to produce low-power and high-speed transistors. A high-performance transistor may be formed by using a semiconductor substrate including the III-V material having a higher mobility of electrons than that of a Si substrate, such as GaAs, and a semiconductor substrate including a semiconductor material having a higher mobility of holes than that of the Si substrate, such as Ge. In some embodiments, the substrate may have a silicon on insulator (SOI) structure. In an embodiment, the base layer 10 may use a silicon substrate.

A semiconductor stacking material layer STC may be formed by alternately stacking a plurality of sacrificial semiconductor layers 12 and a plurality of nanosheet semiconductor layers 14 on the base layer 10. The semiconductor stacking material layer STC includes the plurality of sacrificial semiconductor layers 12 and the plurality of nanosheet semiconductor layers 14. A lowermost sacrificial semiconductor layer may be disposed directly on the base layer and an uppermost nanosheet semiconductor layer of nanosheet semiconductor layers 14 may be an uppermost layer of the semiconductor stacking material layer STC. In an embodiment, four sacrificial semiconductor layers 12 may be provided, and the four nanosheet semiconductor layers 14 may be formed on the base layer 10, but the inventive concept is not limited thereto.

The semiconductor stacking material layer STC may be formed on the first surface 10a of the base layer 10. The sacrificial semiconductor layers 12 and the nanosheet semiconductor layers 14 of the semiconductor stacking material layer STC may be formed by an epitaxial growth method. The sacrificial semiconductor layers 12 and the nanosheet semiconductor layers 14 may include different semiconductor materials.

In some embodiments, the sacrificial semiconductor layers 12 may include SiGe, and the nanosheet semiconductor layers 14 may include Si, but the inventive concept is not limited thereto. The sacrificial semiconductor layers 12 may include a material that may be etched with respect to the nanosheet semiconductor layers 14. Both the sacrificial semiconductor layers 12 and the nanosheet semiconductor layers 14 may be formed to have a same thickness, but the inventive concept is not limited thereto.

Mask patterns 21 spaced apart from each other may be formed on the semiconductor stacking material layer STC. A first opening 22 may be formed between the mask patterns 21. The mask pattern 21 may include a dummy gate pattern 16, a capping pattern 18, and a gate spacer 20. The capping pattern 18 may be formed on the dummy gate pattern 16. The gate spacer 20 may be formed on one sidewall of each of the dummy gate pattern 16 and the capping pattern 18.

In some embodiments, the dummy gate pattern 16 may include a polysilicon layer doped with impurities. The capping pattern 18 may include a silicon nitride layer. The gate spacer 20 may include a silicon oxide layer.

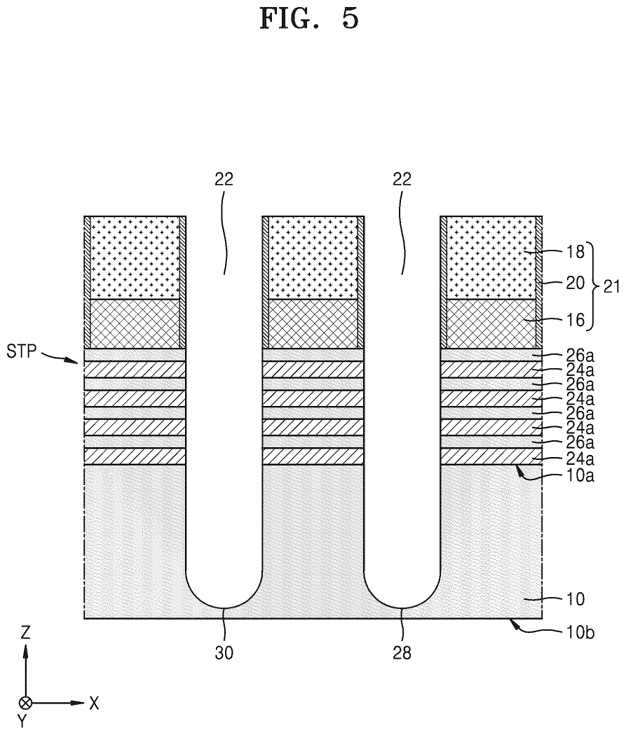

Referring to FIG. 5, a first contact hole 28 and a second contact hole 30 may be formed by etching a portion of each of the semiconductor stacking material layer STC and the base layer 10 by using the mask patterns 21 of FIG. 4 as an etch mask. Accordingly, a semiconductor stacking pattern STP defined by the first contact hole 28 and the second contact hole 30 may be formed on the base layer 10.

The semiconductor stacking pattern STP may include semiconductor patterns 24a and nanosheets 26a. The first contact hole 28 and the second contact hole 30 may be formed inside the semiconductor stacking pattern STP and inside the base layer 10. The first contact hole 28 and the second contact hole 30 may include a region formed below the first surface 10a of the base layer 10.

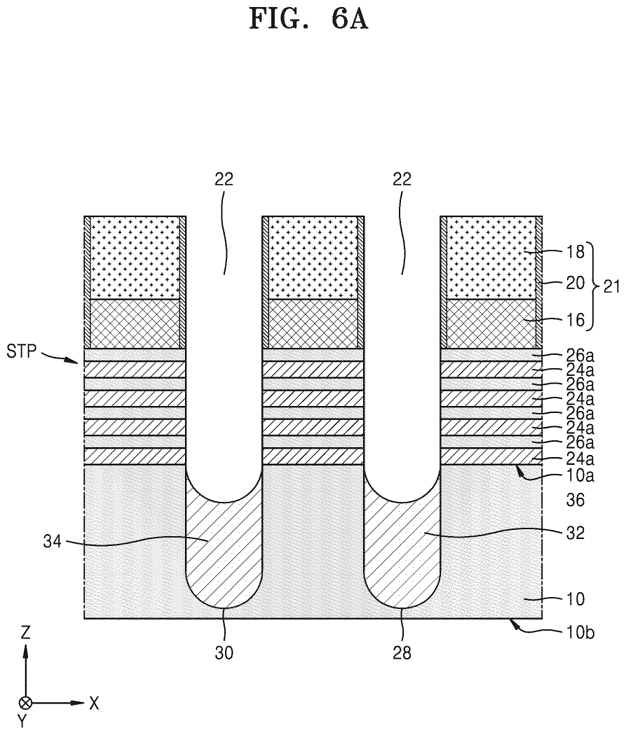

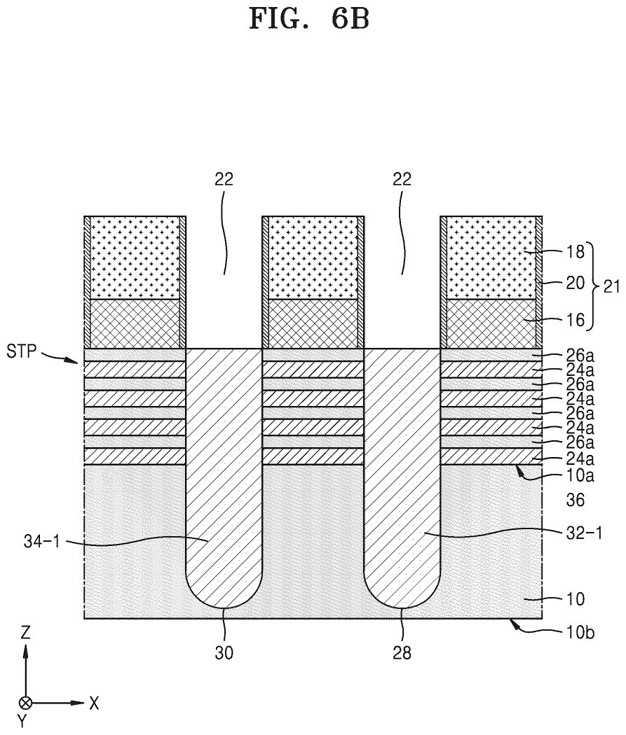

Given the structure of FIG. 5, any one of manufacturing processes of FIG. 6A and FIG. 6B may be selectively performed.

Referring to FIG. 6A, a first epitaxial layer 32 and a second epitaxial layer 34 may be formed in the first contact hole 28 and the second contact hole 30, respectively. The first epitaxial layer 32 and the second epitaxial layer 34 may be formed to fill a portion of the first contact hole 28 and the second contact hole 30, respectively. The first epitaxial layer 32 and the second epitaxial layer 34 may be formed on a region inside the base layer 10.

The first epitaxial layer 32 and the second epitaxial layer 34 may be respectively formed by selectively epitaxially growing semiconductor materials in regions within the first contact hole 28 and the second contact hole 30. In some embodiments, the first epitaxial layer 32 and the second epitaxial layer 34 may be epitaxially grown Si layers, epitaxially grown SiC layers, or epitaxially grown SiGe layers.

Referring to FIG. 6B, a first epitaxial layer 32-1 and a second epitaxial layer 34-1 may be formed in the first contact hole 28 and the second contact hole 30, respectively. The first epitaxial layer 32-1 and the second epitaxial layer 34-1 may be formed inside the base layer 10 and inside the semiconductor stacking pattern STP. The first epitaxial layer 32-1 and the second epitaxial layer 34-1 may fill the first contact hole 28 and the second contact hole 30. The first epitaxial layer 32-1 and the second epitaxial layer 34-1 may have upper surfaces having a height substantially equal to an upper surface of the uppermost nanosheet of the nanosheets 26a.

The first epitaxial layer 32-1 and the second epitaxial layer 34-1 may be respectively formed by selectively epitaxially growing semiconductor materials in the first contact hole 28 and the second contact hole 30. In some embodiments, the first epitaxial layer 32-1 and the second epitaxial layer 34-1 may be epitaxially grown Si layers, epitaxially grown SiC layers, or epitaxially grown SiGe layers.

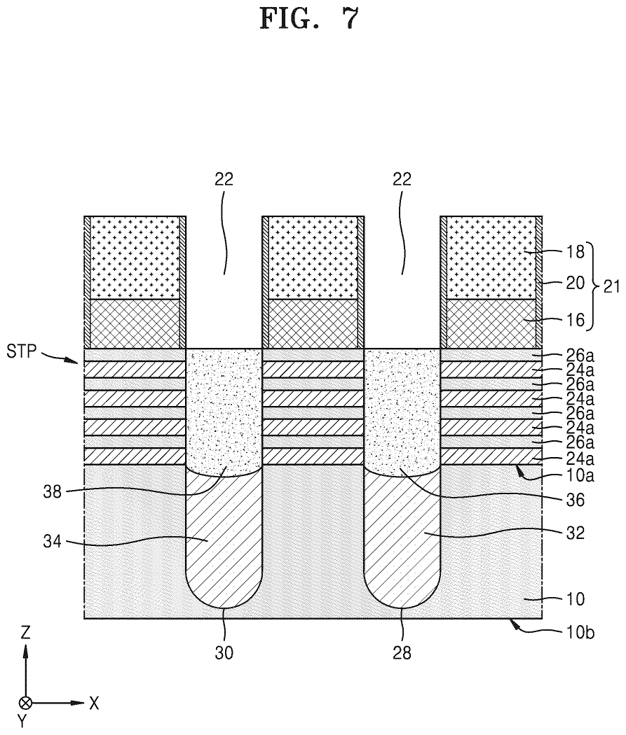

Referring to FIG. 7, given a structure of FIG. 6A or FIG. 6B, the first source and drain region 36 and the second source and drain region 38 may be respectively formed on the first epitaxial layer 32 and the second epitaxial layer 34. The first source and drain region 36 and the second source and drain region 38 may be formed inside the semiconductor stacking pattern STP and on the first surface 10a of the base layer 10.

The first source and drain region 36 and the second source and drain region 38 may be formed by selectively epitaxially growing semiconductor materials doped with impurities on the first epitaxial layer 32 and the second epitaxial layer 34, respectively. In some embodiments, impurities may be boron (B), arsenic (As), or phosphorus (P).

In some embodiments, the first source and drain region 36 and the second source and drain region 38 may include epitaxially grown Si layers doped with impurities, epitaxially grown SiC layers doped with impurities, or epitaxially grown SiGe layers doped with impurities.

Given the structure of FIG. 6B, the first source and drain region 36 and the second source and drain region 38 may be formed by doping partial regions of the first epitaxial layer 32-1 and the second epitaxial layer 34-1 with impurities, respectively. In some embodiments, impurities may be boron (B), arsenic (As), or phosphorus (P). The first source and drain region 36 may be formed on the first epitaxial layer 32-1. The second source and drain region 38 may be formed on the second epitaxial layer 34-1.

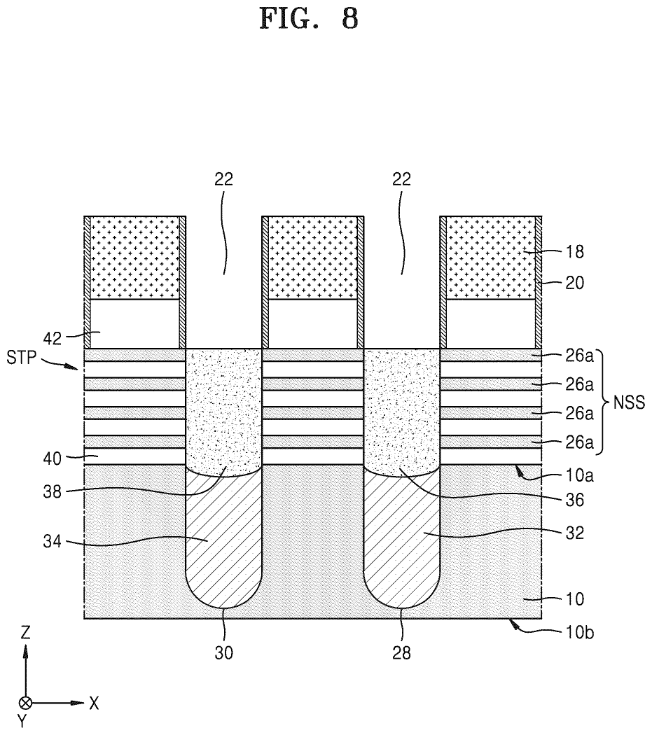

Referring to FIG. 8, the nanosheet stacking structures NSS positioned apart from each other may be formed by selectively removing semiconductor patterns 24a of the semiconductor stacking pattern STP. Accordingly, a second opening 40 may be formed between the nanosheets 26a of the nanosheet stacking structure NSS.

In addition, the dummy gate pattern 16 of FIG. 7 of the mask patterns 21 of FIG. 7 may be selectively removed. Accordingly, the third opening 42 may be formed in the uppermost nanosheet of the nanosheets 26a. The third opening 42 may be formed in a lower portion of the capping pattern 18 and inside the gate spacer 20. In some embodiments, the gate spacer 20 may also be removed when forming the third opening 42.

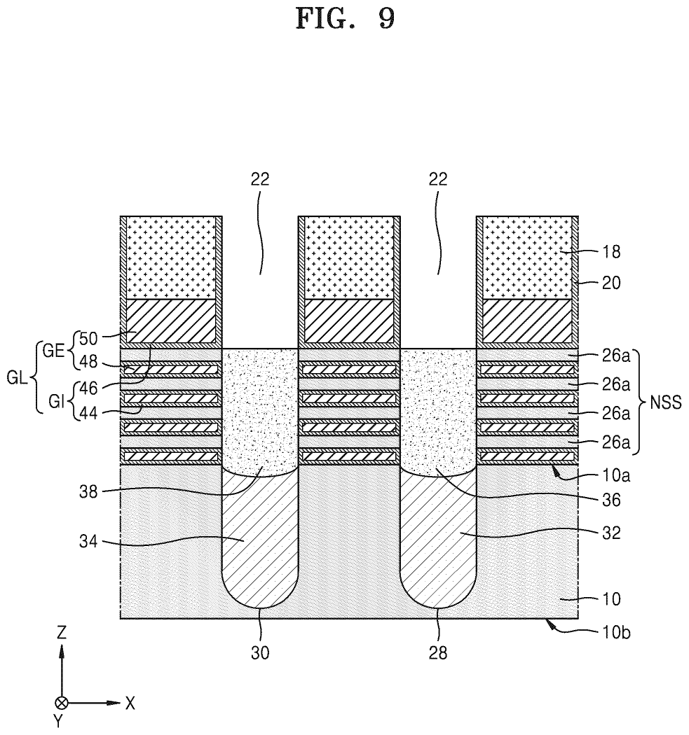

Referring to FIG. 9, the gate insulating layers GI may be formed in the second opening 40 and in the third opening 42. The gate insulating layers GI may be formed on an inner wall of the second opening 40 and a surface of the third opening 42. The gate insulating layers GI may include the sub gate insulating layer 44 formed between the nanosheets 26a and the main gate insulating layer 46 formed on the uppermost nanosheet of the nanosheets 26a.

The gate insulating layers GI may each include a high-k layer. The high-k layer may include a material having a higher dielectric constant than a silicon oxide layer. For example, the high-k layer may have a dielectric constant of about 10 to about 25.

The high-k layer may include a material selected from hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof, the material of the high-k layer is not limited to those described herein.

The high-k layer may be formed by an atomic layer deposition (ALD) process, a chemical vapor deposition (CVD) process, or a physical vapor deposition (PVD) process. The high-k layer may have a thickness of about 10 Angstroms (Å) to about 40 Å, but is not limited thereto.

Subsequently, the gate electrode GE may be formed on the gate insulating layers GI in the second opening 40 and the third opening 42. The gate electrode GE may be formed on the gate insulating layers GI to fill the second opening 40 and the third opening 42. The gate electrode GE may be formed on the gate insulating layers GI in the second opening 40 and the third opening 42. The gate electrode GE may include the sub gate electrode 48 formed between the nanosheets 26a and the main gate electrode 50 formed on the uppermost nanosheet of the nanosheets 26a.

In some embodiments, the gate electrode GE may include a metal layer or a metal nitride layer. The gate electrode GE may include Titanium (Ti), Tungsten (W), Al, Ruthenium (Ru), Niobium (Nb), Molybdenum (Mo), Hafnium (Hf), Nickel (Ni), Cobalt (Co), Platinum (Pt), Ytterbium (Yb), Terbium (Tb), Dysprosium (Dy), Erbium (Er), Palladium (Pd), Titanium Nitride (TIN), Tantalum Nitride (TaN), or at least one selected from among these.

Through this process, the gate structure GL including the gate insulating layers GI and the gate electrode GE may be formed. The gate structure GL may be disposed between the plurality of nanosheets 26a and on the uppermost nanosheet of the nanosheets 26a.

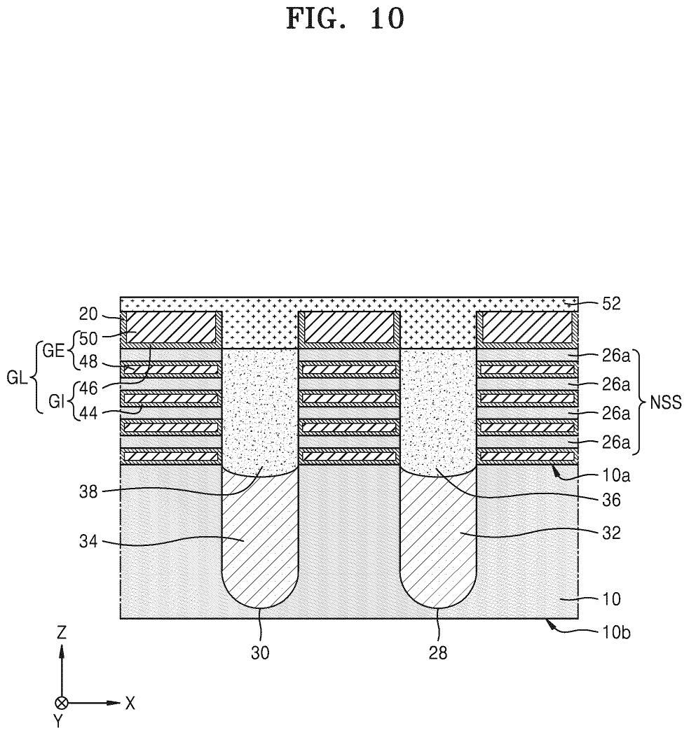

Referring to FIG. 10, a first interlayer insulating layer 52 may be formed in a portion of the first opening 22 of FIG. 9 and on the main gate electrode 50 on the first source and drain region 36 and the second source and drain region 38. The first interlayer insulating layer 52 may include a silicon nitride layer.

The first interlayer insulating layer 52 may be formed by forming a first interlayer insulating material layer in the first opening 22 of FIG. 9 on the first source and drain region 36 and the second source and drain region 38, and on the capping pattern 18 and the gate spacer 20, etching back the first interlayer insulating material layer, and forming a second interlayer insulating material layer on the etched back first interlayer insulating material layer. When forming the first interlayer insulating layer 52, the capping pattern 18 may be removed, and a part of the gate spacer 20 may be etched. When etching back the first interlayer insulating material layer, the surface of the main gate electrode 50 may be used as an etch stop point.

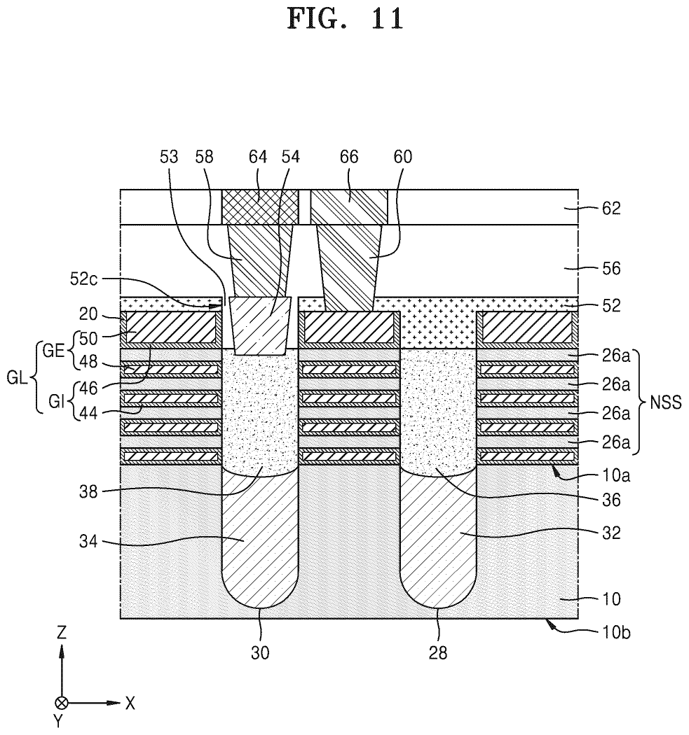

Referring to FIG. 11, a fourth opening 52C may be formed in the first interlayer insulating layer 52. The fourth opening 52C may expose the second source and drain region 38. Subsequently, a sidewall insulating layer 53 and a first contact plug 54 may be formed in the fourth opening 52C. The sidewall insulating layer 53 may include a silicon oxide layer. The first contact plug 54 may contact and be electrically connected to the second source and drain region 38.

A second interlayer insulating layer 56 may be formed on the first interlayer insulating layer 52, the sidewall insulating layer 53, and the first contact plug 54. The second interlayer insulating layer 56 may include a silicon oxide layer. The first via plug 58 may be formed in the second interlayer insulating layer 56. The first via plug 58 may be connected to the first contact plug 54. The second contact plug 60 may be formed in the first interlayer insulating layer 52 and the second interlayer insulating layer 56. The second contact plug 60 may be electrically connected to the uppermost gate electrode 50 of the gate structure GL.

The third interlayer insulating layer 62 may be formed on the first via plug 58 and the second contact plug 60. The third interlayer insulating layer 62 may include a silicon oxide layer. The source and drain metal wiring layer 64 may be formed in the third interlayer insulating layer 62. The source and drain metal wiring layer 64 may be electrically connected to the first via plug 58. Accordingly, the source and drain metal wiring layer 64 may be electrically connected to the second source and drain region 38 through the first via plug 58 and the first contact plug 54.

The gate metal wiring layer 66 may be formed in the third interlayer insulating layer 62. The gate metal wiring layer 66 may be electrically connected to the second contact plug 60. Accordingly, the gate metal wiring layer 66 may be electrically connected to the gate structure GL through the second contact plug 60. The gate metal wiring layer 66 may be electrically connected to the uppermost gate electrode 50 of the gate structure GL through the second contact plug 60.

In some embodiments, after attaching a carrier wafer (not shown) onto the third interlayer insulating layer 62, the source and drain metal wiring layer 64, and the gate metal wiring layer 66, a thickness of the base layer 10 may be reduced. The thickness of the base layer 10 may be reduced by polishing the second surface 10b of the base layer 10.

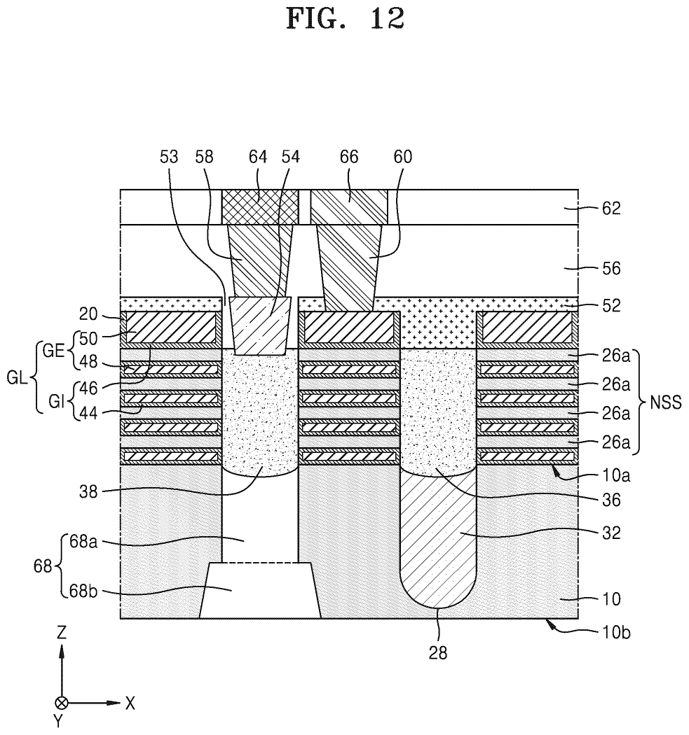

Referring to FIG. 12, a manufacturing process may be performed by turning a structure of FIG. 11 upside down. A fourth opening 68 may be formed by etching a part of the second epitaxial layer 34 in the second contact hole 30 of FIG. 11 of the lower portion of the second source and drain region 38 and a part of the base layer 10.

The fourth opening 68 may expose the second source and drain region 38 in a vertical direction (Z direction) from the second surface 10b of the base layer 10 to the first surface 10a. The fourth opening 68 may include a first sub-opening 68a disposed in the lower portion of the second source and drain region 38 and a second sub-opening 68b exposing the first sub-opening 68a.

A width of the second sub-opening 68b may be greater than a width of the first sub-opening 68a in the first horizontal direction (X direction). A lower surface of the second sub-opening 68b may be coplanar with the second surface 10b of the base layer 10. The second surface 10b of the base layer 10 may be a surface formed following a thinning of the base layer 10.

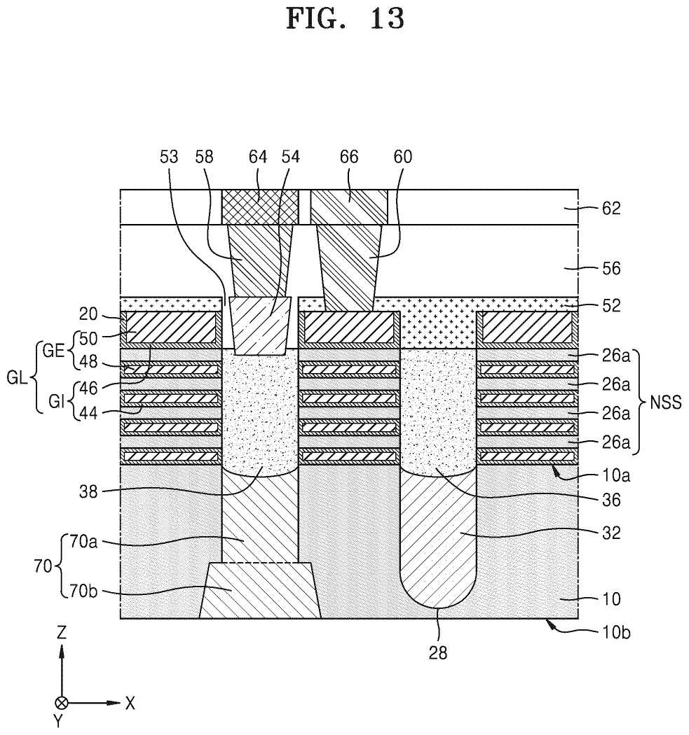

Referring to FIG. 13, the second placeholder 70 may be formed in the fourth opening 68. The second placeholder 70 may be formed by forming an insulating material layer in the fourth opening 68 on the second surface 10b of the base layer 10 and etching back the insulating material layer. The second placeholder 70 may be self-aligned and formed in the second source and drain region 38.

The second placeholder 70 may include an insulating layer, for example, a silicon oxide layer. The second placeholder 70 may include a holder insulating layer 70a contacting the second source and drain region 38 and an insulating via 70b contacting the holder insulating layer 70a. The holder insulating layer 70a and the insulating via 70b may be formed by filling insulating material layers in the first sub-opening 68a and the second sub-opening 68b, respectively.

In some embodiments, when the thickness of the base layer 10 is small, the insulating via 70b may be omitted. In this case, the second placeholder 70 may include the holder insulating layer 70a.

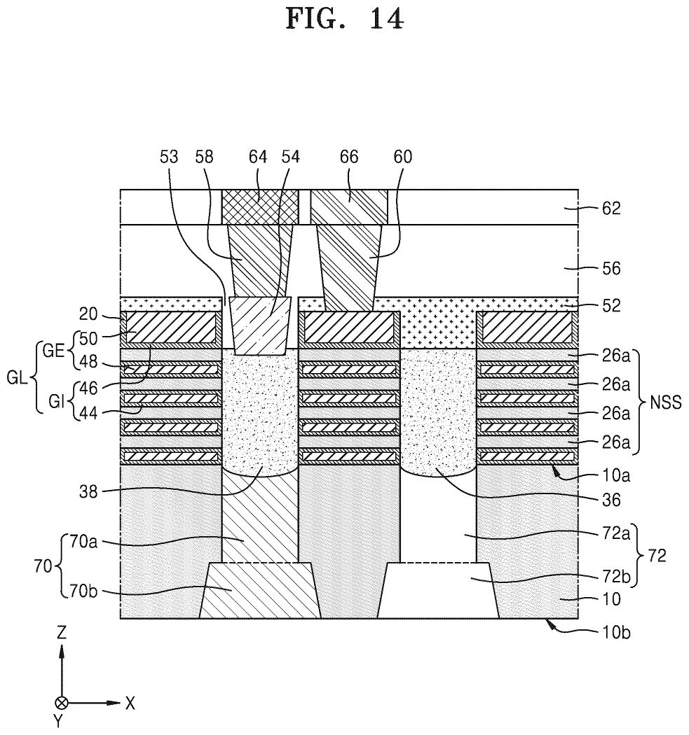

Referring to FIG. 14, a fifth opening 72 may be formed by etching parts of the first epitaxial layer 32 and the base layer 10 in the first contact hole 28 of FIG. 13 in the lower portion of the first source and drain region 36. The fifth opening 72 may expose the first source and drain region 36 in the vertical direction (Z direction) from the second surface 10b of the base layer 10 to the first surface 10a. The fifth opening 72 may include a third sub-opening 72a disposed in a lower portion of the first source and drain region 36 and a fourth sub-opening 72b exposing the third sub-opening 72a.

A width of the fourth sub-opening 72b may be greater than a width of the third sub-opening 72a in the first horizontal direction (X direction). A lower surface of the fourth sub-opening 72b may be coplanar with the second surface 10b of the base layer 10. The second surface 10b of the base layer 10 may be a surface formed following a thinning of the base layer 10.

Subsequently, referring to FIG. 2, the first placeholder 74 and the rail via 75 may be formed in the fifth opening 72 of FIG. 14. The first placeholder 74 and the rail via 75 may be formed by forming a metal layer in the fifth opening 72 of FIG. 14 on the second surface 10b of the base layer 10 and etching back the metal layer. The first placeholder 74 and the rail via 75 may be self-aligned and formed in the first source and drain region 36.

The first placeholder 74 and the rail via 75 may each include a metal layer. The first placeholder 74 and the rail via 75 may be formed as a single body. The first placeholder 74 and the rail via 75 may be formed by filling metal layers in the third sub-opening 72a of FIG. 14 and the fourth sub-opening 72b of FIG. 14, respectively. In some embodiments, when the thickness of the base layer 10 is small, the rail via 75 may be omitted.

The metal power rail 76 may be formed on the second placeholder 70 and the rail via 75. The metal power rail 76 may be formed on the rail via 75 and the insulating via 70b on the second surface 10b of the base layer 10. The metal power rail 76 may be formed to extend in the first horizontal direction (X direction) on the second surface 10b of the base layer 10.

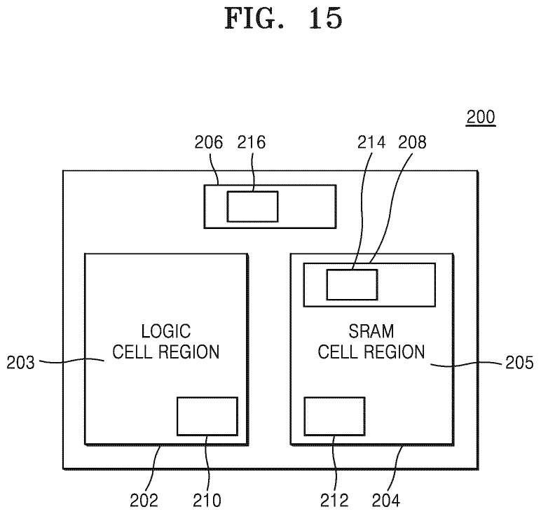

FIG. 15 is a block diagram illustrating a configuration of a semiconductor chip including an integrated circuit semiconductor device according to an embodiment.

A semiconductor chip 200 may include a logic region 202, a static random access memory (SRAM) region 204, and an input/output region 206. The logic region 202 may include a logic cell region 203. The SRAM region 204 may include an SRAM cell region 205 and an SRAM peripheral circuit region 208.

A first transistor 210 may be disposed in the logic cell region 203, and a second transistor 212 may be disposed in the SRAM cell region 205. A third transistor 214 may be formed in the SRAM peripheral circuit region 208, and a fourth transistor 216 may be disposed in the input/output region 206.

The semiconductor chip 200 may include the integrated circuit semiconductor device 100 according to an embodiment. In some embodiments, the first transistor 210, the second transistor 212, the third transistor 214, and the fourth transistor 216 may each include an MBC described herein.

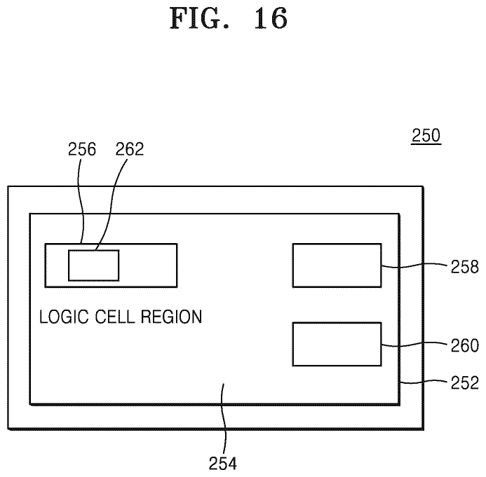

FIG. 16 is a block diagram illustrating a configuration of a semiconductor chip including an integrated circuit semiconductor device according to an embodiment.

In detail, a semiconductor chip 250 may include a logic region 252. The logic region 252 may include a logic cell region 254 and an input/output region 256. A first transistor 258 and a second transistor 260 may be disposed in the logic cell region 254. The first transistor 258 and the second transistor 260 may be transistors having different conductivity types. A third transistor 262 may be disposed in the input/output region 256.

The semiconductor chip 250 may include the integrated circuit semiconductor device 100 according to an embodiment. In some embodiments, the first transistor 258, the second transistor 260, and the third transistor 262 may each include an MBC described herein.

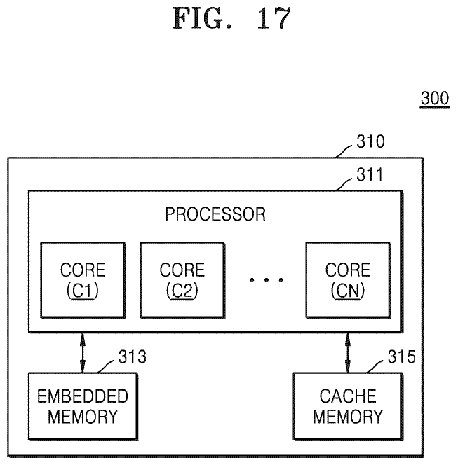

FIG. 17 is a block diagram illustrating a configuration of an electronic device including an integrated circuit semiconductor device according to an embodiment.

An electronic device 300 may include a system-on-chip 310. The system-on-chip 310 may include a processor 311, an embedded memory 313, and a cache memory 315. The processor 311 may include one or more processor cores C1 to CN. The processor cores C1 to CN may process data and signals. The processor cores C1 to CN may each include the integrated circuit semiconductor device 100 according to some embodiments.

The electronic device 300 may perform its own function by using the processed data and signals. For example, the processor 311 may be an application processor. The embedded memory 313 may exchange first data DAT1 with the processor 311. The first data DAT1 is data processed or to be processed by the processor cores C1 to CN. The embedded memory 313 may manage the first data DAT1.

For example, the embedded memory 313 may buffer the first data DAT1. The embedded memory 313 may operate as buffer memory or working memory of the processor 311.

The embedded memory 313 may be SRAM. The SRAM may operate at higher speeds than dynamic random access memory (DRAM). When the SRAM is embedded in the system-on-chip 310, the electronic device 300 having a small size and operating at a high speed may be implemented. Furthermore, when the SRAM is embedded in the system-on-chip 310, and consumption of power by the electronic device 300 may be reduced.

For example, the SRAM may include the integrated circuit semiconductor device 100 according to some embodiments. The cache memory 315 may be mounted on the system-on-chip 310 together with the processor cores C1 to CN. The cache memory 315 may store cache data DATc. The cache data DATc may be data used by the processor cores C1 to CN. The cache memory 315 may have a small storage capacity, but may operate at a high speed.

For example, the cache memory 315 may include an SRAM including the integrated circuit semiconductor device 100 according to some embodiments. When the cache memory 315 is used, the number of times and time that the processor 311 accesses the embedded memory 313 may be reduced. Accordingly, when the cache memory 315 is used, the operating speed of the electronic device 300 may be increased. For better understanding, in FIG. 17, the cache memory 315 is shown as a component separate from the processor 311. However, the cache memory 315 may be configured to be included in the processor 311.

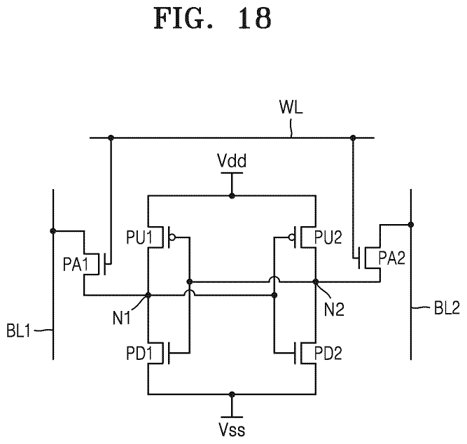

FIG. 18 is an equivalent circuit diagram of an SRAM cell according to an embodiment.

The SRAM cell may be implemented through the integrated circuit semiconductor device 100 according to an embodiment. For example, the SRAM cell may be applied to the embedded memory 313 and/or the cache memory 315 described with reference to FIG. 17.

The SRAM cell may include a first pull-up transistor PU1, a first pull-down transistor PD1, a second pull-up transistor PU2, a second pull-down transistor PD2, a first access transistor PA1, and a second access transistor PA2.

The first pull-up transistor PU1 and the second pull-up transistor PU2 may be P-type MOS transistors, while the first pull-down transistor PD1 and the second pull-down transistor PD2 and the first access transistor PA1 and the second access transistor PA2 may be N-type MOS transistors.

The first pull-up transistor PU1 and the first pull-down transistor PD1 may form a first inverter. Connected gate electrodes (gates) of the first pull-up transistor PU1 and the first pull-down transistor PD1 may correspond to input terminals of the first inverter, and a first node N1 may correspond to an output terminal of the first inverter.

The second pull-up transistor PU2 and the second pull-down transistor PD2 may form a second inverter. Connected gate electrodes (gates) of the second pull-up transistor PU2 and the second pull-down transistor PD2 may correspond to input terminals of the second inverter, and a second node N2 may correspond to an output terminal of the second inverter.

The first and second inverters may be combined with each other to form a latch structure. The gate electrodes of the first pull-up transistor PU1 and the first pull-down transistor PD1 may be electrically connected to the second node N2, and the gate electrodes of the second pull-up transistor PU2 and the second pull-down transistor PD2 may be electrically connected to the first node N1.

A first source/drain of the first access transistor PA1 may be connected to the first node N1, and a second source/drain of the first access transistor PA1 may be connected to a first bit line BL1. A first source/drain of the second access transistor PA2 may be connected to the second node N2, and a second source/drain of the second access transistor PA2 may be connected to a second bit line BL2.

Gate electrodes of the first access transistor PA1 and the second access transistor PA2 may be electrically connected to a word line WL. Accordingly, the SRAM cell may be implemented by using the integrated circuit semiconductor device 100 according to some embodiments.

While the inventive concept has been particularly shown and described with reference to embodiments thereof, it will be understood that various changes in form and details may be made therein without departing from the spirit and scope of the following claims.

What is claimed is:

1. An integrated circuit semiconductor device comprising:
a base layer comprising a first surface and a second surface opposite to the first surface;
a gate structure on the first surface of the base layer;
a first source and drain region on a first side of the gate structure;
a second source and drain region on a second side of the gate structure;
a first placeholder disposed in the base layer in a lower portion of the first source and drain region and electrically connected to the first source and drain region;
a second placeholder disposed in the base layer in a lower portion of the second source and drain region;
a metal power rail disposed on the first placeholder and the second placeholder on the second surface of the base layer and electrically connected to the first placeholder; and
a source and drain metal wiring layer electrically connected to the second source and drain region on the first surface of the base layer.

2. The integrated circuit semiconductor device of claim 1, wherein the first placeholder includes a metal layer disposed in the base layer and contacting the first source and drain region in the base layer.

3. The integrated circuit semiconductor device of claim 1, wherein the second placeholder includes an insulating layer disposed in the base layer and contacting the second source and drain region in the base layer.

4. The integrated circuit semiconductor device of claim 1, wherein the base layer includes a bulk substrate or an insulating layer.

5. The integrated circuit semiconductor device of claim 1, wherein the metal power rail is disposed on the second surface of the base layer and extends in a first horizontal direction.

6. The integrated circuit semiconductor device of claim 5, wherein the source and drain metal wiring layer is disposed on a portion of the first surface of the base layer and extends in a second horizontal direction perpendicular to the first horizontal direction.

7. The integrated circuit semiconductor device of claim 1, wherein the metal power rail is electrically connected to the first placeholder through a rail via.

8. The integrated circuit semiconductor device of claim 1, wherein the source and drain metal wiring layer is electrically connected to the second source and drain region through a via plug.

9. The integrated circuit semiconductor device of claim 1, wherein the gate structure comprises a gate insulating layer and a gate electrode, and wherein a gate metal wiring layer electrically connected to the gate electrode through a contact plug is further disposed on the gate structure.

10. An integrated circuit semiconductor device comprising:
a base layer comprising a first surface and a second surface opposite to the first surface;
a nanosheet stacking structure disposed on the first surface of the base layer and comprising a plurality of nanosheets spaced apart from each other in a vertical direction;
a gate structure disposed between the plurality of nanosheets and on an uppermost nanosheet of the plurality of nanosheets;
a first source and drain region on a first side of the gate structure;
a second source and drain region on a second side of the gate structure;
a first placeholder contacting the first source and drain region in the base layer in a lower portion of the first source and drain region and comprising a metal layer;
a second placeholder contacting the second source and drain region in the base layer in a lower portion of the second source and drain region and comprising an insulating layer;
a metal power rail disposed on the second surface of the base layer and electrically connected to the first placeholder; and
a source and drain metal wiring layer disposed on the nanosheet stacking structure and the gate structure and electrically connected to the second source and drain region.

11. The integrated circuit semiconductor device of claim 10, wherein the first placeholder is disposed in the base layer and contacts the first source and drain region in a vertical direction from the second surface of the base layer to the first surface.

12. The integrated circuit semiconductor device of claim 10, wherein the second placeholder is disposed in the base layer and contacts the second source and drain region in a vertical direction from the second surface of the base layer to the first surface.

13. The integrated circuit semiconductor device of claim 10, wherein the base layer includes a bulk substrate or an insulating layer.

14. The integrated circuit semiconductor device of claim 10, wherein the metal power rail is disposed on the second surface of the base layer and extends in a first horizontal direction, and the source and drain metal wiring layer is disposed on the second source and drain region and extends in a second horizontal direction perpendicular to the first horizontal direction.

15. The integrated circuit semiconductor device of claim 10, wherein the metal power rail is electrically connected to the first placeholder through a rail via, and the source and drain metal wiring layer is electrically connected to the second source and drain region through a via plug.

16. The integrated circuit semiconductor device of claim 10, wherein the gate structure comprises a plurality of gate insulating layers and a plurality of gate electrodes, and wherein a gate metal wiring layer electrically connected to the plurality of gate electrodes through a contact plug is further disposed on the gate structure.

17. An integrated circuit semiconductor device comprising:
a substrate comprising a first surface and a second surface opposite to the first surface;
a nanosheet stacking structure disposed on the first surface of the substrate and comprising a plurality of nanosheets spaced apart from each other in a vertical direction;
a gate structure disposed between the plurality of nanosheets and on an uppermost nanosheet of the plurality of nanosheets and comprising a plurality of gate insulating layers and a plurality of gate electrodes;
a first source and drain region on a first side of the gate structure on the first surface of the substrate;
a second source and drain region on a second side of the gate structure on the first surface of the substrate, wherein the first side is opposite to the second side;
a first placeholder contacting the first source and drain region in the substrate in a lower portion of the first source and drain region and comprises a metal layer;
a second placeholder contacting the second source and drain region in the substrate in a lower portion of the second source and drain region and comprises an insulating layer;
a metal power rail disposed on the first placeholder and the second placeholder on the second surface of the substrate, electrically connected to the first placeholder through a rail via, and electrically insulated from the second placeholder;
a source and drain metal wiring layer disposed on the nanosheet stacking structure and the gate structure, and electrically connected to the second source and drain region through a via plug; and
a gate metal wiring layer disposed on the gate structure and electrically connected to the plurality of gate electrodes through a contact plug.

18. The integrated circuit semiconductor device of claim 17, wherein the metal power rail is disposed on the second surface of the substrate and extends in a first horizontal direction, and
a width of the rail via is greater than a width of the first placeholder in the first horizontal direction.

19. The integrated circuit semiconductor device of claim 18, wherein the source and drain metal wiring layer is disposed on the second source and drain region and extends in a second horizontal direction perpendicular to the first horizontal direction, and
the gate metal wiring layer is disposed on the gate structure and extends in the second horizontal direction.

20. The integrated circuit semiconductor device of claim 17, wherein the first placeholder and the rail via are formed as a single body.
